(19) United States
(12) Patent Application Publication
(10) Pub. No.: US 2025/0188313 A1
(43) Pub. Date: Jun. 12, 2025

(54) FILM AND LAMINATE

(71) Applicant: FUJIFILM Corporation, Tokyo (JP)

(72) Inventors: Shohei YAMAZAKI, Kanagawa (JP); Yasuyuki SASADA, Kanagawa (JP); Hitoshi IKEDA, Kanagawa (JP)

(73) Assignee: FUJIFILM Corporation, Tokyo (JP)

(21) Appl. No.: 19/056,743

(22) Filed: Feb. 19, 2025

Related U.S. Application Data
(63) Continuation of application No. PCT/JP2023/029985, filed on Aug. 21, 2023.

(30) Foreign Application Priority Data
Aug. 31, 2022 (JP) 2022-138491

(51) Int. Cl. C09D 177/12; H05K 3/38

(52) U.S. Cl. CPC C09D 177/12; H05K 3/389

(57) ABSTRACT

A film includes a layer A having a dielectric loss tangent of 0.01 or less, a thermal expansion coefficient of 30 ppm/K to 70 ppm/K, and a porosity of 20% by volume to 60% by volume.

### CROSS-REFERENCE TO RELATED APPLICATION

This application is a continuation application of International Application No. PCT/JP2023/029985 filed Aug. 21, 2023, which claims priority from Japanese Patent Application No. 2022-138491 filed Aug. 31, 2022. The entire disclosure of each of the above applications is incorporated herein by reference.

### BACKGROUND OF THE INVENTION

### 1. Field of the Invention

The present disclosure relates to a film and a laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent.

As the insulating material, a resin composition including polyimide or the like is used, and in recent years, a filler has been added to the resin composition for the purpose of further reducing the dielectric loss tangent.

As a resin composition for following and adhering to a circuit board in the related art, for example, JP2019-199612A discloses a resin composition including a styrene-based polymer, an inorganic filler, and a curing agent, in which the styrene-based polymer is an acid-modified styrene-based polymer having a carboxyl group, the inorganic filler is silica and/or aluminum hydroxide, a particle diameter of the inorganic filler is 1 μm or less, a content of the inorganic filler is 20 to 80 parts by mass with respect to 100 parts by mass of the styrene-based polymer, and the resin composition satisfies Expression (A) and Expression (B) in a form of a film having a thickness of 25 μm.

$$X \leq 50 \qquad ( A )$$

$$Y \geq 40 \qquad ( B )$$

(In the expression, X represents an absorbance (unit: %) of light having a wavelength of 355 nm, and Y represents a haze value (unit: %).)

### SUMMARY OF THE INVENTION

In a case where a filler is added to the above-described resin composition, curl may occur in a layer formed of the resin composition, and there is a concern that the adhesiveness to a circuit board or the like may be reduced.

On the other hand, it is also conceivable to use a filler having a low thermal expansion coefficient (CTE), but the present inventors have recently found that the breaking elongation of a layer formed of the resin composition may decrease.

An object to be achieved by an embodiment of the present disclosure is to provide a film having excellent curl suppressing property and high breaking elongation.

Further, an object to be achieved by another embodiment of the present disclosure is to provide a laminate formed of the film.

The present disclosure includes the following aspects.

<1> A film including: a layer A having a dielectric loss tangent of 0.01 or less, a thermal expansion coefficient of 30 ppm/K to 70 ppm/K, and a porosity of 20% by volume to 60% by volume.

<2> The film according to <1>, in which an elastic modulus of the layer A at 25° C. is 1.0 GPa or more.

<3> The film according to <1> or <2>, in which a bulk density of the layer A is 1.3 g/cm³ or less.

<4> The film according to any one of <1> to <3>,
in which a layer B is provided on at least one surface of the layer A,
an elastic modulus of the layer A at 160° C. is 0.1 GPa to 2.5 GPa, and
a ratio of an elastic modulus of the layer A at 160° C. to an elastic modulus of the layer B at 160° C. is 1.2 or more.

<5> The film according to <4>, in which the elastic modulus of the layer B at 160° C. is 0.1 GPa or less.

<6> The film according to any one of <1> to <5>, in which the layer A contains a liquid crystal polymer.

<7> The film according to any one of <1> to <6>, in which the layer A contains an aromatic polyester amide.

<8> The film according to <4> or <5>, in which a dielectric loss tangent of the layer B is 0.01 or less.

<9> The film according to <4>, <5>, or <8>, in which the layer B contains a liquid crystal polymer.

<10> The film according to <4>, <5>, <8>, or <9>, in which the layer B contains an aromatic polyester amide.

<11> The film according to <4>, <5>, <8>, <9>, or <10>, in which the layer B contains at least one of a resin having a constitutional unit having an aromatic hydrocarbon group or an elastomer having a constitutional unit having an aromatic hydrocarbon group.

<12> A laminate including, in the following order:
a layer A; and
a metal layer or a metal wire,
in which the layer A has a dielectric loss tangent of the layer A is 0.01 or less, a thermal expansion coefficient of the layer A is 30 ppm/K to 70 ppm/K, and a porosity of the layer A is 20% by volume to 60% by volume.

According to one embodiment of the present disclosure, it is possible to provide a film having excellent curl suppressing property and high breaking elongation.

Further, according to another aspect of the present disclosure, it is possible to provide a laminate formed of the film.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit value or a lower limit value in another numerical range described in a stepwise manner. Further, in a numerical range described in the present disclosure, an upper limit value or a lower limit value described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, “(meth)acryl” is a term that is used in a concept including both acrylic and methacryl.

Further, the term “step” in the present specification indicates not only an independent step but also a step which cannot be clearly distinguished from other steps as long as the intended purpose of the step is achieved.

Further, in the present disclosure, “% by mass” has the same definition as that for “% by weight”, and “part by mass” has the same definition as that for “part by weight”.

In the present disclosure, the term “solid content” means components excluding a solvent.

Furthermore, in the present disclosure, a combination of two or more preferred embodiments is a more preferred embodiment.

In the present disclosure, the dielectric loss tangent is measured by the following method.

The dielectric loss tangent is measured by a resonance perturbation method at a frequency of 28 GHz. A 28 GHz cavity resonator (CP531 manufactured by KANTO Electronic Application and Development Inc.) is connected to a network analyzer (“E8363B” manufactured by Agilent Technology Co., Ltd.), a test piece is inserted into the cavity resonator, and the dielectric loss tangent of the film is measured from change in resonance frequency before and after insertion for 96 hours under an environment of a temperature of 25° C. and humidity of 60% RH.

In a case where each layer is measured, an unnecessary layer may be scraped off with a razor or the like to produce an evaluation sample of only the target layer. In addition, in a case where it is difficult to take out the single film because the thickness of the layer is thin, a layer to be measured may be scraped off with a razor or the like, and the obtained powdery sample may be used.

In the present disclosure, the measurement of the dielectric loss tangent of the polymer is carried out according to the above-described measuring method of a dielectric loss tangent by identifying or isolating a chemical structure of the polymer constituting each layer and using a powdered sample of the polymer to be measured.

In addition, in the present disclosure, a weight-average molecular weight (Mw) is a molecular weight converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

Further, examples of a method for detecting or determining the layer configuration, the thickness of each layer, and the like in the film include the following methods.

First, a cross-sectional sample of the film is cut out by a microtome, and a layer configuration and a thickness of each layer are determined with an optical microscope. In a case where the determination with an optical microscope is difficult, the determination may be obtained by performing morphological observation with a scanning electron microscope (SEM), or component analysis by a time-of-flight secondary ion mass spectrometry (TOF-SIMS) or the like.

Hereinafter, a film and a laminate according to the embodiment of the present disclosure will be described in detail.

### (Film)

The film according to the embodiment of the present disclosure has a layer A having a dielectric loss tangent of 0.01 or less, a thermal expansion coefficient of 30 ppm/K to 70 ppm/K, and a porosity of 20% by volume to 60% by volume.

The film according to the embodiment of the present disclosure has excellent curl suppressing property and has high breaking elongation. The reason why the above-described effect is exhibited is not clear, but is presumed as follows.

The layer A of the film according to the embodiment of the present disclosure has a porosity of 20% by volume or more and is structurally difficult to deform. Therefore, it is presumed that the occurrence of curling can be suppressed even in a case where the layer A contains a filler.

In addition, it is presumed that the layer A has a thermal expansion coefficient of 30 ppm/K or more and high molecular mobility, and thus the breaking elongation of the film is improved.

### <Average Thickness of Film>

From the viewpoint of strength and electrical characteristics (characteristic impedance) in a case of being laminated with the metal layer, an average thickness of the film according to the embodiment of the present disclosure is preferably 6 μm to 200 μm, more preferably 12 μm to 100 μm, and particularly preferably 20 μm to 80 μm.

A measuring method of the film and the average thickness of each layer according to the embodiment of the present disclosure is as follows.

The film is cut with a microtome to produce a sample. The cross section of the sample is observed with an optical microscope, and the thickness of each layer is measured. The sample is cut out at three or more positions from the film, the thickness is measured at three or more points in each cross section, and the average value of the obtained measured values is defined as the average thickness.

### <Dielectric Loss Tangent of Film>

From the viewpoint of transmission loss, the dielectric loss tangent of the film according to the embodiment of the present disclosure is preferably 0.01 or less, more preferably 0.008 or less, still more preferably 0.005 or less, particularly preferably 0.004 or less, and most preferably more than 0 and 0.003 or less.

### —Layer A—

The layer A has a dielectric loss tangent of 0.01 or less, a thermal expansion coefficient of 30 ppm/K to 70 ppm/K, and a porosity of 20% by volume to 60% by volume.

### <Dielectric Loss Tangent of Layer A>

From the viewpoint of transmission loss, the dielectric loss tangent of the layer A at 28 GHz is preferably 0.008 or less, more preferably 0.005 or less, still more preferably 0.004 or less, and particularly preferably more than 0 and 0.003 or less.

### <Thermal Expansion Coefficient (CTE) of Layer A>

From the viewpoint of the processing suitability of the film, the thermal expansion coefficient of the layer A is preferably 35 ppm/K to 65 ppm/K, more preferably 40 ppm/K to 60 ppm/K, and still more preferably 45 ppm/K to 55 ppm/K.

In the present disclosure, the thermal expansion coefficient of the layer A is measured as follows.

The film according to the embodiment of the present disclosure is cut with a microtome to produce a film sample having a width of 5 mm and a length of 20 mm. The linear expansion coefficient is calculated from the slope of the TMA curve between 30° C. and 150° C. when the temperature is raised from 25° C. to 200° C. at a rate of 5° C./min, lowered to 30° C. at a rate of 20° C./min, and raised again at a rate of 5° C./min, by applying a tensile load of 1 g to both ends of the film sample using a thermomechanical analysis device (TMA).

The thermal expansion coefficient of the layer A can be adjusted by changing the type, the content, and the like of the material (for example, a liquid crystal polymer, a filler, and the like) contained in the layer A.

### <Porosity of Layer A>

From the viewpoint of curl suppressing property and strength, the porosity of the layer A is preferably 20% by volume to 50% by volume, more preferably 20% by volume to 40% by volume, and still more preferably 20% by volume to 30% by volume.

In the present disclosure, the porosity of the layer A is measured as follows.

A region of the layer A in the film having an area of 500 μm×500 μm in the in-plane direction is scanned along the film thickness direction of the layer A by the X-ray CT method, and the region is distinguished between a gas (air) and the other (solid and liquid).

Then, from the three-dimensional image data obtained by performing image processing on a plurality of scanning layers obtained by scanning along the film thickness direction, the volume of the gas (void portion) which is present in the scanned region and total volume of the scanned region (total volume of gas, solid, and liquid) are obtained.

Then, the proportion of the volume of the gas to the total volume of the scanned region is defined as the porosity (% by volume) of the layer A.

The porosity of the layer A can be adjusted by changing the type, the content, and the like of the material (for example, a liquid crystal polymer, a filler, and the like) contained in the layer A. In addition, the porosity of the layer A can be adjusted by changing the content of the solvent, the drying conditions, and the like in the composition used for forming the layer A.

### <Elastic Modulus of Layer a at 160° C. and 25° C.>

From the viewpoint of laser processing suitability and level difference followability, the elastic modulus of the layer A in the film according to the embodiment of the present disclosure at 160° C. is preferably 0.1 GPa to 2.5 GPa, more preferably 0.2 GPa to 2.0 GPa, still more preferably 0.3 GPa to 1.5 GPa, and particularly preferably 0.5 GPa to 1.0 GPa.

From the viewpoint of laser processing suitability and level difference followability, the elastic modulus of the layer A in the film according to the embodiment of the present disclosure at 25° C. is preferably 1.0 GPa or more, more preferably 1.0 GPa to 4.0 GPa, still more preferably 1.5 GPa to 3.5 GPa, and particularly preferably 1.7 GPa to 3.2 GPa.

The “laser processing suitability” in the present disclosure is a characteristic in that excessive cutting by a laser can be reduced in a case where cutting processing by a laser, particularly through-hole processing is performed, and it can be said that the “laser processing suitability” is excellent in a case where the above-described characteristic is excellent, and the workability of a cutting portion in laser processing into a desired shape is excellent.

In the present disclosure, the elastic moduli of the layer A and the layer B are measured as follows.

First, the film according to the embodiment of the present disclosure is cut into a cross section with a microtome or the like, and the layer A or the layer B is specified with an optical microscope. Next, the elastic modulus of the specified layer A or layer B is measured as an indentation elastic modulus using a nanoindentation method.

The indentation elastic modulus is measured by using a microhardness tester (for example, product name “DUH-W201”, manufactured by Shimadzu Corporation) to apply a load at a loading rate of 0.28 mN/sec with a Vickers indenter at 25° C. or 160° C., holding a maximum load of 10 mN for 10 seconds, and then unloading at a loading rate of 0.28 mN/sec.

The elastic modulus of the layer A can be adjusted by changing the type, the content, and the like of the material (for example, a liquid crystal polymer, a filler, and the like) contained in the layer A.

### <Bulk Density of Layer A>

From the viewpoint of curl suppressing property and strength, the bulk density of the layer A is preferably 1.3 g/cm³ or less, more preferably 0.9 g/cm³ to 1.3 g/cm³, still more preferably 1.0 g/cm³ to 1.2 g/cm³, and particularly preferably 1.0 g/cm³ to 1.1 g/cm³.

In the present disclosure, the bulk density of the layer A is measured as follows.

In the present disclosure, the bulk density of the layer A is measured by an Archimedes method.

The bulk density of the layer A can be adjusted by changing the type, the content, and the like of the material (for example, a liquid crystal polymer, a filler, and the like) contained in the layer A. In addition, the bulk density of the layer A can be adjusted by changing the content of the solvent in the composition used for forming the layer A.

### —Liquid Crystal Polymer—

From the viewpoint of dielectric loss tangent of the film, laser processing suitability, and level difference followability, the layer A preferably contains a liquid crystal polymer.

In the present disclosure, the type of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. Further, in a case where the liquid crystal polymer is a thermotropic liquid crystal polymer, the liquid crystal polymer is preferably a liquid crystal polymer which is molten at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, from the viewpoints of the dielectric loss tangent, the liquid crystallinity, and the thermal expansion coefficient of the film, the liquid crystal polymer is preferably a polymer having an aromatic ring, more preferably an aromatic polyester or an aromatic polyester amide, and particularly preferably an aromatic polyester amide.

Further, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

Further, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated hydroxy group into an acyloxy group.

For example, the aromatic hydroxycarboxylic acid, the aromatic diol, and the aromatic hydroxyamine can be each replaced with an acylated product by acylating a hydroxy group and converting the acylated hydroxy group into an acyloxy group.

Examples of a polymerizable derivative of a compound having an amino group, such as an aromatic hydroxyamine or an aromatic diamine, include a derivative (acylated product) obtained by acylating an amino group and converting the acylated amino group to an acylamino group.

For example, the aromatic hydroxyamine and the aromatic diamine can be each replaced with an acylated product by acylating an amino group and converting the acylated amino group into an acylamino group.

From the viewpoint of liquid crystallinity, the dielectric loss tangent of the film, and adhesiveness to the metal, the liquid crystal polymer preferably has a constitutional unit represented by any of Formulae (1) to (3) (hereinafter, a constitutional unit represented by Formula (1) or the like may be referred to as a constitutional unit (1) or the like), more preferably has a constitutional unit represented by Formula (1), and particularly preferably has a constitutional unit represented by Formula (1), a constitutional unit represented by Formula (2), and a constitutional unit represented by Formula (3).

—O—Ar¹-CO— Formula (1)

—CO—Ar²—CO— Formula (2)

—X—Ar³-Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group.

-Ar⁴-Z-Ar⁵- Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group. The number of carbon atoms in the alkyl group is preferably 1 to 10.

Examples of the aryl group include a phenyl group, an o-tolyl group, an m-tolyl group, a p-tolyl group, a 1-naphthyl group, and a 2-naphthyl group. The number of carbon atoms in the aryl group is preferably 6 to 20.

In a case where the hydrogen atom is substituted with any of these groups, the number of each of substitutions in Ar¹, Ar², and Ar³ independently is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group. The number of carbon atoms in the alkylene group is preferably 1 to 10.

The constitutional unit (1) is a constitutional unit derived from an aromatic hydroxycarboxylic acid.

As the constitutional unit (1), an aspect in which Ar¹ represents a p-phenylene group (constitutional unit derived from p-hydroxybenzoic acid), an aspect in which Ar¹ represents a 2,6-naphthylene group (constitutional unit derived from 6-hydroxy-2-naphthoic acid), or an aspect in which Ar¹ represents a 4,4′-biphenylylene group (constitutional unit derived from 4′-hydroxy-4-biphenylcarboxylic acid) is preferable.

The constitutional unit (2) is a constitutional unit derived from an aromatic dicarboxylic acid.

As the constitutional unit (2), an aspect in which Ar² represents a p-phenylene group (constitutional unit derived from terephthalic acid), an aspect in which Ar² represents an m-phenylene group (constitutional unit derived from isophthalic acid), an aspect in which Ar² represents a 2,6-naphthylene group (constitutional unit derived from 2,6-naphthalenedicarboxylic acid), or an aspect in which Ar² represents a diphenylether-4,4′-diyl group (constitutional unit derived from diphenylether-4,4′-dicarboxylic acid) is preferable.

The constitutional unit (3) is a constitutional unit derived from an aromatic diol, an aromatic hydroxylamine, or an aromatic diamine.

As the constitutional unit (3), an aspect in which Ar³ represents a p-phenylene group (constitutional unit derived from hydroquinone, p-aminophenol, or p-phenylenediamine), an aspect in which Ar³ represents an m-phenylene group (constitutional unit derived from isophthalic acid), or an aspect in which Ar³ represents a 4,4′-biphenylylene group (constitutional unit derived from 4,4′-dihydroxybiphenyl, 4-amino-4′-hydroxybiphenyl, or 4,4′-diaminobiphenyl) is preferable.

The content of the constitutional unit (1) is preferably 30 mol % or more, more preferably 30 mol % to 80 mol %, still more preferably 30 mol % to 60 mol %, and particularly preferably 30 mol % to 40 mol % with respect to the total amount of all constitutional units. The total amount of all the constitutional units refers to a value obtained by dividing the mass of each constitutional unit (also referred to as a “monomer unit”) that constitutes the liquid crystal polymer by the formula weight of each constitutional unit to calculate the corresponding amount (mole) of substance of each constitutional unit, and summing the amounts.

The content of the constitutional unit (2) is preferably 35 mol % or less, more preferably 10 mol % to 35 mol %, still more preferably 20 mol % to 35 mol %, and particularly preferably 30 mol % to 35 mol % with respect to the total amount of all constitutional units.

The content of the constitutional unit (3) is preferably 35 mol % or less, more preferably 10 mol % to 35 mol %, still more preferably 20 mol % to 35 mol %, and particularly preferably 30 mol % to 35 mol % with respect to the total amount of all constitutional units.

The heat resistance, the strength, and the rigidity are likely to be improved as the content of the constitutional unit (1) increases, but the solubility in a solvent is likely to be decreased in a case where the content thereof is extremely large.

The proportion of the content of the constitutional unit (2) to the content of the constitutional unit (3) is preferably 0.9/1 to 1/0.9, more preferably 0.95/1 to 1/0.95, and still more preferably 0.98/1 to 1/0.98. The proportion of the content of the constitutional unit (2) to the content of the constitutional unit (3) is a proportion represented by [content of constitutional unit (2)]/[content of constitutional unit (3)] (mol/mol).

The liquid crystal polymer may have two or more kinds of each of the constitutional units (1) to (3) independently. In addition, the liquid crystal polymer may have a constitutional unit other than the units (1) to (3). A content of the constitutional unit other than the constitutional units (1) to (3) is preferably 10 mol % or less and more preferably 5 mol % or less with respect to the total amount of all constitutional units.

From the viewpoint of solubility in a solvent, the liquid crystal polymer preferably has, as the constitutional unit (3), a constitutional unit (3) in which at least one of X or Y is an imino group, that is, preferably has as the constitutional unit (3), at least one of a constitutional unit derived from an aromatic hydroxylamine or a constitutional unit derived from an aromatic diamine, and it is more preferable to have only a constitutional unit (3) in which at least one of X or Y is an imino group.

It is preferable that the liquid crystal polymer is produced by melt-polymerizing raw material monomers corresponding to the constitutional units constituting the liquid crystal polymer. The melt polymerization may be carried out in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole; and preferred examples thereof include nitrogen-containing heterocyclic compounds. The melt polymerization may be further carried out by solid-state polymerization as necessary.

The lower limit value of the flow start temperature of the liquid crystal polymer is preferably 180° C. or higher, more preferably 200° C. or higher, and still more preferably 250° C. or higher. The upper limit value of the flow start temperature of the liquid crystal polymer is preferably 350° C., more preferably 330° C., and still more preferably 310° C. In a case where the flow start temperature of the liquid crystal polymer is within the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pa·s (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of the liquid crystal polymer (see p. 95 of “Liquid Crystal Polymers—Synthesis/Molding/Applications—”, written by Naoyuki Koide, CMC Corporation, Jun. 5, 1987).

In addition, a weight-average molecular weight of the liquid crystal polymer is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, a film after heat treatment is excellent in thermal conductivity, heat resistance, strength, and rigidity in the thickness direction.

The liquid crystal polymer is preferably a polymer (soluble polymer) soluble in a specific organic solvent.

Specifically, the soluble polymer according to the embodiment of the present disclosure is a polymer that is preferably dissolved in 0.1 g or more (the solubility is 0.1% by mass), more preferably in 0.5 g or more (the solubility is 0.5% by mass), and still more preferably in 1.0 g or more (the solubility is 1% by mass) at 25° C. in 100 g of at least one solvent (preferably N-methylpyrrolidone) selected from the group consisting of N-methylpyrrolidone, N-ethylpyrrolidone, dichloromethane, dichloroethane, chloroform, N,N-dimethylacetamide, γ-butyrolactone, dimethylformamide, ethylene glycol monobutyl ether, and ethylene glycol monoethyl ether.

The layer A may contain only one or two or more kinds of the liquid crystal polymers.

The content of the liquid crystal polymer with respect to the total mass of the layer A is not particularly limited, and it is preferably appropriately adjusted according to the use application and the like, and it can be set to 10% by mass to 100% by mass.

From the viewpoint of thermal expansion coefficient and dielectric loss tangent, the layer A may contain a filler.

The filler may be a particulate filler or a fibrous filler, and may be an inorganic filler or an organic filler, but from the viewpoint of laser processing suitability of the film, an organic filler is preferable.

In the film according to the embodiment of the present disclosure, from the viewpoint of the thermal expansion coefficient and the adhesiveness to the metal, the number density of the filler is preferably larger inside the film than the surface of the film.

Here, the surface of the film refers to a surface (surface in contact with air or substrate) of the film outside, and a smaller one of a range of 3 μm in a depth direction from the most surface or a range of 10% or less of the thickness of the entire film from the most surface is defined as the “surface”. The inside of the film refers to a portion other than the surface of the film, that is, a surface (a surface not in contact with air or a substrate) inside the film, and is not limited, but in a range of ±1.5 μm from the center in the thickness direction of the film or in a range of ±5% of the total thickness from the center in the thickness direction of the film, one having a smaller numerical value is defined as “inside”.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent of the film, the laser processing suitability, and the level difference followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and crushing the liquid crystal polymer with a crusher or the like to obtain powdery liquid crystal. The liquid crystal polymer particles are preferably smaller than the thickness of each layer.

In addition, in the layer A, from the viewpoint of favorably forming voids, the average particle diameter of the organic filler is preferably 5 μm to 30 μm, more preferably 7 μm to 25 μm, and still more preferably 8 μm to 15 μm, from the viewpoint of the dielectric loss tangent of the film, the laser processing suitability, and the level difference followability.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of thermal expansion coefficient and adhesiveness to the metal, metal oxide particles or fibers are preferable, silica particles, titania particles, or glass fibers are more preferable, and silica particles or glass fibers are particularly preferable.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, in the layer A, from the viewpoint of favorably forming voids, the average particle diameter of the inorganic filler is preferably 5 μm to 30 μm, more preferably 7 μm to 25 μm, and still more preferably 8 μm to 15 μm, from the viewpoint of dielectric loss tangent of the film, laser processing suitability, and level difference followability.

The layer A may contain only one or two or more kinds of the fillers.

In addition, from the viewpoint of laser processing suitability and dielectric loss tangent, the content of the filler with respect to the total mass of the layer A is preferably 5% by mass to 90% by mass, more preferably 30% by mass to 85% by mass, still more preferably 50% by mass to 80% by mass, and particularly preferably 60% by mass to 77% by mass.

In addition, in the layer A, from the viewpoint of favorably forming voids, the content of the filler is preferably in the above-described numerical range.

### —Other Additives—

The layer A may contain an additive other than the above-described components.

Known additives can be used as other additives. Specific examples of the other additives include a curing agent, a leveling agent, an antifoaming agent, an antioxidant, an ultraviolet absorbing agent, a flame retardant, and a colorant.

In addition, the layer A may contain other resins other than the above-described polymer and polymer particles as other additives.

Examples of other resins include thermoplastic resins such as polypropylene, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The average thickness of the layer A is not particularly limited, but from the viewpoint of electrical characteristics (characteristic impedance) in a case of being made into a laminate with the metal layer, it is preferably 5 μm to 90 μm, more preferably 10 μm to 70 μm, and particularly preferably 15 μm to 60 μm.

In a case where the film according to the embodiment of the present disclosure has the layer B described later, from the viewpoint of dielectric loss tangent of the film and adhesiveness to the metal, it is preferable that the average thickness of the layer A is larger than the average thickness of the layer B.

From the viewpoint of dielectric loss tangent of the film and adhesiveness to the metal, a value of T^{A}/T^{B}, which is a ratio of the average thickness T^{A} of the layer A to the average thickness T^{B} of the layer B, is preferably 0.8 to 10, more preferably 1 to 5, still more preferably more than 1 and 3 or less, and particularly preferably more than 1 and 2 or less.

### —Layer B—

The film according to the embodiment of the present disclosure can include the layer B on at least one surface of the layer A.

### <Dielectric Loss Tangent of Layer B>

From the viewpoint of dielectric constant, the dielectric loss tangent of the layer B at 28 GHz is preferably 0.01 or less, more preferably 0.008 or less, still more preferably 0.005 or less, particularly preferably 0.004 or less, and most preferably more than 0 and 0.003 or less.

### <Elastic Modulus of Layer B at 160° C. and 25° C.>

From the viewpoint of laser processing suitability and level difference followability, the elastic modulus of the layer B in the film according to the embodiment of the present disclosure at 160° C. is preferably 0.1 GPa or less, more preferably 0.01 GPa or less, still more preferably 0.001 MPa to 0.01 GPa, and particularly preferably 0.0005 MPa to 0.005 GPa.

In a case where the film according to the embodiment of the present disclosure includes the layer B, from the viewpoint of laser processing suitability and level difference followability, a ratio (MD^{A}/MD^{B}) of the elastic modulus MD^{A} of the layer A at 160° C. to the elastic modulus MD^{B} of the layer B at 160° C. is preferably 1.2 or more.

### —Liquid Crystal Polymer—

From the viewpoint of dielectric loss tangent of the film, laser processing suitability, and level difference followability, the layer B preferably contains a liquid crystal polymer. The details of the liquid crystal polymer are the same as those of the layer A, including the preferred aspect, and thus the description thereof will be omitted here.

The layer B may contain only one or two or more kinds of the liquid crystal polymers.

From the viewpoint of dielectric loss tangent of the film and adhesiveness to the metal, a content of the liquid crystal polymer with respect to the total mass of the layer B is preferably 10% by mass to 100% by mass, more preferably 15% by mass to 70% by mass, still more preferably 20% by mass to 50% by mass, and particularly preferably 25% by mass to 40% by mass.

### —Resin Having Constitutional Unit Having Aromatic Hydrocarbon Group and Elastomer Having Constitutional Unit Having Aromatic Hydrocarbon Group—

From the viewpoint of dielectric loss tangent of the film, laser processing suitability, and level difference followability, the layer B preferably contains at least one of a resin having a constitutional unit having an aromatic hydrocarbon group or an elastomer having a constitutional unit having an aromatic hydrocarbon group.

The form of the resin and the elastomer is not particularly limited, but from the viewpoint of dielectric loss tangent of the film, laser processing suitability, and level difference followability, a particle shape is preferable.

Examples of the constitutional unit having an aromatic hydrocarbon group include a phenylethylene group.

The resin having a constitutional unit having an aromatic hydrocarbon group is not limited as long as the resin has a constitutional unit having an aromatic hydrocarbon group, and a thermoplastic resin having a constitutional unit having an aromatic hydrocarbon group is preferable. Examples of the thermoplastic resin having a constitutional unit having an aromatic hydrocarbon group include a polyurethane resin, a polyester resin, a (meth)acrylic resin, a polystyrene resin, a fluororesin, a polyimide resin, a fluorinated polyimide resin, a polyamide resin, a polyamideimide resin, a polyether imide resin, a cellulose acylate resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

The elastomer having a constitutional unit having an aromatic hydrocarbon group is not limited as long as the elastomer has a constitutional unit having an aromatic hydrocarbon group, and examples thereof include an elastomer (polystyrene-based elastomer) having a constitutional repeating unit derived from styrene, a polyester-based elastomer, a polyolefin-based elastomer, a polyurethane-based elastomer, a polyamide-based elastomer, a polyacrylic elastomer, a silicone-based elastomer, and a polyimide-based elastomer. The thermoplastic elastomer may be a hydride.

Examples the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), and hydrides thereof.

In the present disclosure, the elastomer represents a compound exhibiting elastic deformation. That is, the elastomer is defined as a compound having a property of being instantly deformed according to an external force in a case where the external force is applied and of being recovered to an original shape in a short time in a case where the external force is removed.

It is preferable that the elastomer has a property in which, in a case where the original size is 100%, the elastomer can be deformed up to 200% at room temperature (20° C.) with a small external force and the elastomer is returned to 110% or less in a short time in a case where the external force is removed.

In addition, from the viewpoint of dielectric loss tangent of the film, laser processing suitability, and level difference followability, the weight-average molecular weight of the resin and the elastomer is preferably 1,000,000 or less, more preferably 3,000 to 300,000, still more preferably 5,000 to 100,000, and particularly preferably 5,000 to 30,000.

From the viewpoint of dielectric loss tangent of the film, laser processing suitability, and level difference followability, the layer B more preferably contains a polystyrene-based elastomer, still more preferably contains a hydrogenated polystyrene-based elastomer, and even still more preferably contains a hydrogenated styrene-ethylene-butylene-styrene block copolymer.

From the viewpoint of dielectric loss tangent of the film, laser processing suitability, and level difference followability, a sum of the contents of the resin and the elastomer with respect to the total mass of the layer B is preferably 50% by mass or more, more preferably 50% by mass to 95% by mass, and still more preferably 60% by mass to 85% by mass.

The layer B may contain only one kind of thermoplastic particles or may contain two or more kinds thereof.

### —Other Additives—

The layer B may contain an additive other than the above-described components. Since the other additives are the same as those in the layer A, the description thereof will be omitted here.

In addition, the layer B may contain a filler in the same manner as the layer A. In a case where the resin having a constitutional unit having an aromatic hydrocarbon group and the elastomer having a constitutional unit having an aromatic hydrocarbon group are particles, these are not included in the filler.

An average thickness of the layer B is not particularly limited, but from the viewpoints of the dielectric loss tangent of the film, the laser processing suitability, and the level difference followability, the average thickness is preferably 1 μm to 90 μm, more preferably 5 μm to 60 μm, and particularly preferably 10 μm to 40 μm.

The film according to the embodiment of the present disclosure includes the layer B, and thus a film having excellent adhesiveness to the metal can be obtained. For example, in a case where the layer A has a filler, it is presumed that, by including the layer B and the layer A brittle due to the addition of the filler, the surface of the film is improved, and effects such as improvement in adhesiveness are obtained.

In addition, the layer B is preferably a surface layer (outermost layer). For example, in a case where the film is used as a laminate (laminated plate with a metal layer) having a layer configuration of metal layer/layer A/layer B, another metal layer or laminated plate with a metal layer may be further disposed on the layer B side. In this case, interface destruction between the layer B and another metal layer in the laminate is suppressed, and the adhesiveness to the metal is improved.

In addition, it is preferable that the polymer contained in the layer B contains a polymer having a higher breaking strength (toughness) that the polymer contained in the layer A.

The breaking strength is measured by the following method.

A sample including the polymer to be measured is produced, and using a universal tensile tester “STM T50BP” manufactured by Toyo Baldwin Co., Ltd., a stress against elongation is measured at a tensile rate of 10%/min in an atmosphere of 25° C. and 60% RH to obtain the breaking strength.

### —Layer C—

The film according to the embodiment of the present disclosure preferably further has a layer C, and from the viewpoint of adhesiveness to the metal, more preferably has the layer C, the layer A, and the layer B in this order.

The layer C is preferably an adhesive layer.

In addition, in a case where a metal layer is present separately from each of the above-described layers, the layer C is preferably a surface layer (outermost layer).

From the viewpoint of dielectric loss tangent of the film, the layer C preferably contains a polymer having a dielectric loss tangent of 0.01 or less at 28 GHz.

Examples of the polymer having a dielectric loss tangent of 0.01 or less include thermoplastic resins such as a liquid crystal polymer, a fluorine-based polymer, a polymerized substance of a compound which has a cyclic aliphatic hydrocarbon group and a group having an ethylenically unsaturated bond, polyether ether ketone, polyolefin, polyamide, polyester, polyphenylene sulfide, aromatic polyether ketone, polycarbonate, polyethersulfone, polyphenylene ether and modified products thereof, and polyetherimide; elastomers such as a copolymer of glycidyl methacrylate and polyethylene; and thermosetting resins such as a phenol resin, an epoxy resin, a polyimide resin, and a cyanate resin.

The polymer having a dielectric loss tangent of 0.01 or less may be a liquid crystal polymer. From the viewpoint of dielectric loss tangent, liquid crystallinity, and thermal expansion coefficient of the film, the liquid crystal polymer is preferably a polymer having an aromatic ring, and more preferably an aromatic polyester resin.

From the viewpoints of the dielectric loss tangent of the film and the adhesiveness to the metal, the content of the polymer having a dielectric loss tangent of 0.01 or less with respect to the total mass of the layer C is preferably 50% by mass to 99% by mass, more preferably 80% by mass to 99% by mass, still more preferably 90% by mass to 99% by mass, and particularly preferably 95% by mass to 99% by mass.

In addition, from the viewpoint of the dielectric loss tangent of the film and the laser processing suitability, the layer C preferably includes a polymer having an aromatic ring, and more preferably includes a polymer having an aromatic ring, and being a resin having an ester bond and an amide bond, and having a dielectric loss tangent of 0.01 or less.

In addition, the layer C preferably contains an epoxy resin since the metal layer and the resin layer (for example, the layer A) are adhered to each other.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

The layer C may or may not include other additives. Since this is the same as the first composition, the description thereof will be omitted here.

From the viewpoint of dielectric loss tangent of the film and adhesiveness to the metal, it is preferable that an average thickness of the layer C is smaller than an average thickness of the layer A.

From the viewpoint of dielectric loss tangent of the film and adhesiveness to the metal, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

From the viewpoint of dielectric loss tangent of the film and adhesiveness to the metal, a value of T^{B}/T^{C}, which is a ratio of the average thickness T^{B} of the layer B to the average thickness T^{C} of the layer C, is preferably more than 1, more preferably 2 to 100, still more preferably 3 to 50, and particularly preferably 4 to 30.

Further, from the viewpoint of the dielectric loss tangent of the film and the adhesiveness to the metal, the average thickness of the layer C is preferably 0.1 nm to 20 μm, more preferably 0.1 nm to 5 μm, and still more preferably 1 nm to 1 μm.

### <Manufacturing Method of Film>

### [Film Formation]

A manufacturing method of the film according to the embodiment of the present disclosure is not particularly limited, and a known method can be referred to.

Suitable examples of the manufacturing method of the film according to the embodiment of the present disclosure include a co-casting method, a multilayer coating method, and a co-extrusion method. Among these, the co-casting method is particularly preferable for formation of a relatively thin film, and the co-extrusion method is particularly preferable for formation of a thick film.

In a case where the film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Two or more kinds of solvents may be used.

The solvent preferably contains an aprotic compound (particularly preferably, an aprotic compound having no halogen atom) for low corrosiveness and easiness to handle. A proportion of the aprotic compound to the whole solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to contain an amide such as N,N-dimethylformamide, N,N-dimethylacetamide, tetramethylurea, and N-methylpyrrolidone, or an ester such as γ-butyrolactone; and it is more preferable to contain N,N-dimethylformamide, N,N-dimethylacetamide, or N-methylpyrrolidone.

In addition, as the solvent, it is preferable to contain a compound having a dipole moment of 3 to 5, because the above-described polymer such as the liquid crystal polymer can be easily dissolved. A proportion of the compound having a dipole moment of 3 to 5 to the whole solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, it is preferable to contain a compound having a boiling point of 220° C. or lower at 1 atm, because the solvent is easily removed. A proportion of the compound having a boiling point of 220° C. or lower at 1 atm to the whole solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

It is preferable that the content of the solvent contained in the composition for forming a layer A, the composition for forming a layer B, and the composition for forming a layer C is appropriately changed depending on the use application and the like.

From the viewpoint of favorably forming voids in the layer A, the content of the solvent with respect to the total mass of the composition for forming the layer A is preferably 50% by mass or more, more preferably 50% by mass to 90% by mass, still more preferably 60% by mass to 85% by mass, and even still more preferably 70% by mass to 85% by mass.

After applying the composition for forming the layer A, the composition for forming the layer B, and the composition for forming the layer C, drying may be performed, and it is preferable to appropriately adjust the drying temperature.

From the viewpoint of being able to favorably forming voids in the layer A, the drying temperature is preferably 50° C. to 150° C. and more preferably 50° C. to 75° C.

In addition, in a case where the manufacturing method of the film according to the embodiment of the present disclosure is the co-casting method, the multilayer coating method, the co-extrusion method, or the like described above, a support may be used in the manufacturing method of the film according to the embodiment of the present disclosure. In addition, in a case where the metal layer (metal foil) or the like used in the laminate described later is used as the support, the support may be used as it is without being peeled off.

Examples of the support include a metal drum, a metal band, a glass plate, a resin film, and a metal foil. Among these, a metal drum, a metal band, or a resin film is preferable.

Examples of the resin film include a polyimide (PI) film, and examples of commercially available products thereof include U-PILEX S and U-PILEX R (manufactured by UBE Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the support is not particularly limited, but is preferably 25 μm or more and 75 μm or less and more preferably 50 μm or more and 75 μm or less.

In addition, a method for removing at least a part of the solvent from a cast or applied film-like composition (a casting film or a coating film) is not particularly limited, and a known drying method can be used.

### [Stretching]

In the film according to the embodiment of the present disclosure, stretching can be combined as appropriate from the viewpoint of controlling molecular alignment and adjusting linear expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the film, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

In addition, the manufacturing method of the film according to the embodiment of the present disclosure may include a step of polymerizing the film by light or heat, as necessary.

A light irradiation means and a heat application means are not particularly limited, and a known light irradiation means such as a metal halide lamp and a known heat application unit such as a heater can be used.

Light irradiation conditions and heat application conditions are not particularly limited, and the polymerization can be carried out at a desired temperature and time and in a known atmosphere.

### [Heat Treatment]

The manufacturing method of the film according to the embodiment of the present disclosure preferably includes a step of subjecting the film to a heat treatment (annealing).

Specifically, from the viewpoint of dielectric loss tangent and peel strength, the heat treatment temperature in the above-described step of heat-treating is preferably 260° C. to 370° C., more preferably 280° C. to 360° C., and still more preferably 300° C. to 350° C. The heat treatment time is preferably 15 minutes to 10 hours and more preferably 30 minutes to 5 hours.

In addition, the manufacturing method of the film according to the embodiment of the present disclosure may include other known steps as necessary.

### <Applications>

The film according to the embodiment of the present disclosure can be used for various applications. Among the various applications, the film can be used suitably as a film for an electronic component such as a printed wiring board and more suitably for a flexible printed circuit board.

In addition, the film according to the embodiment of the present disclosure can be suitably used as a film for metal adhesion.

### (Laminate)

The laminate according to the embodiment of the present disclosure may be a laminate in which the film according to the embodiment of the present disclosure is laminated, but is preferably a laminate including the film according to the embodiment of the present disclosure and a metal layer or a metal wire disposed on at least one surface of the film.

In addition, in the laminate according to the embodiment of the present disclosure, it is preferable that the laminate includes the layer A and the metal layer or the metal wire in this order, in which the layer A has a dielectric loss tangent of 0.01 or less, a thermal expansion coefficient of 30 ppm/K to 70 ppm/K, and a porosity of 20% by volume to 60% by volume.

In addition, it is preferable that the laminate according to the embodiment of the present disclosure has a layer B between the layer A and the metal layer or the metal wire.

In addition, it is preferable that the laminate according to the embodiment of the present disclosure includes the film according to the embodiment of the present disclosure and a metal layer disposed on a surface of the above-described layer B side of the film, and it is more preferable that the metal layer is a copper layer.

The metal layer disposed on the surface of the above-described layer B side is preferably a metal layer disposed on the surface of the above-described layer B.

In addition, it is preferable that the laminate according to the embodiment of the present disclosure includes the film according to the embodiment of the present disclosure in which the layer B, the layer A, and the layer C are provided in this order, a metal layer disposed on a surface of the above-described layer B side of the film, and a metal layer disposed on a surface of the above-described layer C side of the film; and it is more preferable that both of the metal layers are copper layers.

It is preferable that the metal layer disposed on the surface of the above-described layer C side is a metal layer disposed on the surface of the above-described layer C, and it is more preferable that the metal layer disposed on the surface of the above-described layer B side is a metal layer disposed on the surface of the above-described layer B, and the metal layer disposed on the surface of the above-described layer C side is a metal layer disposed on the surface of the above-described layer C.

In addition, the metal layer disposed on the surface of the above-described layer B side and the metal layer disposed on the surface of the above-described layer C side may be a metal layer having the same material, thickness, and shape, or may be metal layers having different materials, thicknesses, and shapes. From the viewpoint of adjusting the characteristic impedance, the metal layer disposed on the surface of the above-described layer B side and the metal layer disposed on the surface of the above-described layer C side may be metal layers having different materials or thicknesses, or a metal layer may be laminated on only one side of the layer B or the layer C.

Furthermore, from the viewpoint of adjusting the characteristic impedance, preferred examples thereof also include an aspect in which a metal layer is laminated on one side of the layer B or the layer C, and another film is laminated on the other side.

A method of attaching the film according to the embodiment of the present disclosure to the metal layer is not particularly limited, and a known laminating method can be used.

In a case where the above-described metal layer is the above-described copper layer, a peel strength between the above-described film and the above-described copper layer is preferably 0.5 kN/m or more, more preferably 0.7 kN/m or more, still more preferably 0.7 kN/m to 2.0 kN/m, and particularly preferably 0.9 kN/m to 1.5 kN/m.

In the present disclosure, the eel strength between the film and the metal layer (for example, the copper layer) is measured by the following method.

A peeling test piece with a width of 1.0 cm is produced from the laminate of the film and the metal layer, the film is fixed to a flat plate with double-sided adhesive tape, and the strength (kN/m) in a case of peeling the film off from the metal layer at a rate of 50 mm/min is measured by the 1800 method in conformity with JIS C 5016 (1994).

From the viewpoint of reducing transmission loss of high-frequency signal, a surface roughness Rz of the above-described metal layer on the side in contact with the above-described film is preferably less than 1 μm, more preferably 0.5 μm or less, and particularly preferably 0.3 μm or less.

Since it is preferable that the surface roughness Rz of the above-described metal layer is as small as possible, the lower limit value thereof is not particularly set, but may be, for example, 0 or more.

The “surface roughness Rz” in the present disclosure refers to a value expressed in micrometer, which is the total value of the maximum value of height of peak and the maximum value of depth of valley observed on a roughness curve over the reference length.

In the present disclosure, the surface roughness Rz of the metal layer (for example, the copper layer) is measured by the following method.

Using a noncontact surface/layer cross-sectional shape measurement system VertScan (manufactured by MITSUBISHI CHEMICAL SYSTEMS, Inc.), a square of 465.48 μm in length and 620.64 μm in width is measured to create a roughness curve on the surface of the measurement object (metal layer) and create an average line of the roughness curve. A portion corresponding to the reference length is extracted from the roughness curve. The surface roughness Rz of the measurement object is measured by obtaining the total value of the maximum value of height of peak (that is, height from the average line to summit) and the maximum value of depth of valley (that is, depth from the average line to valley bottom) observed in the extracted roughness curve.

The metal layer is preferably a copper layer. As the copper layer, a rolled copper foil formed by a rolling method, an electrolytic copper foil formed by an electrolytic method, a copper foil formed by a sputtering method, or a copper foil formed by a vapor deposition method is preferable.

An average thickness of the metal layer, preferably the copper layer, is not particularly limited, but is preferably 0.1 nm to 30 μm, more preferably 0.1 μm to 20 μm, and still more preferably 1 μm to 18 μm. The copper foil may be copper foil with a carrier formed on a support (carrier) to be peelable.

As the carrier, a known carrier can be used. An average thickness of the carrier is not particularly limited, but is preferably 5 μm to 100 μm and more preferably 10 μm to 50 μm.

In addition, from the viewpoint of further exerting the effects of the present disclosure, the above-described metal layer preferably has a known surface treatment layer (for example, a chemical treatment layer) on the surface of the side in contact with the film to ensure adhesion to the resin. In addition, it is also preferable that the metal layer has an interactable group with the film on a surface on a side in contact with the film. The above-described interactable group is preferably a group capable of interacting with the functional group contained in the compound contained in the film.

Examples of the interactable group include at least one group selected from the group consisting of a covalent-bondable group, an ion-bondable group, a hydrogen-bondable group, and a dipole-interactable group.

Among these, as the interactable group, from the viewpoint of adhesiveness and ease of performing a treatment, a covalent-bondable group is preferable, an amino group or a hydroxy group is more preferable, and an amino group is particularly preferable.

The metal layer in the laminate according to the embodiment of the present disclosure may be a metal layer having a circuit pattern.

It is also preferable that the metal layer in the laminate according to the embodiment of the present disclosure is processed into, for example, a desired circuit pattern by etching to form a flexible printed circuit board. The etching method is not particularly limited, and a known etching method can be used.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

In addition, in the present examples, unless otherwise specified, “%” and “part” mean “% by mass” and “part by mass” respectively.

### <<Measurement Method>>

### [Elastic Modulus]

First, the film was cut in cross section with a microtome or the like, and the layer A or the layer B was specified with an optical microscope. Next, the elastic modulus of the specified layer A or layer B was measured as an indentation elastic modulus using a nanoindentation method. The indentation elastic modulus was measured by using a microhardness tester (product name “DUH-W201”, manufactured by Shimadzu Corporation) to apply a load at a loading rate of 0.28 mN/sec with a Vickers indenter at 160° C., holding a maximum load of 10 mN for 10 seconds, and then unloading at a loading rate of 0.28 mN/sec.

### [Bulk Density]

The bulk density of the layer A was measured by an Archimedes method.

### [Porosity]

A region of the layer A in the film having an area of 500 μm×500 μm in the in-plane direction was scanned along the film thickness direction of the layer Aby the X-ray CT method, and the region was distinguished between a gas (air) and the other (solid and liquid).

Then, from the three-dimensional image data obtained by performing image processing on a plurality of scanning layers obtained by scanning along the film thickness direction, the volume of the gas (void portion) which is present in the scanned region and total volume of the scanned region (total volume of gas, solid, and liquid) were obtained.

Then, the proportion of the volume of the gas to the total volume of the scanned region was defined as the porosity (% by volume) of the layer A.

### [Thermal Expansion Coefficient (CTE)]

The film was cut with a microtome to produce a section sample, and the section sample was set in an optical microscope comprising a heating stage system (HS82, manufactured by METTLER TOLEDO).

Subsequently, the thickness (ts30) of the layer A at 30° C. and the thickness (ts150) of the layer A at 150° C. in a case where the temperature was raised from 25° C. to 200° C. at a rate of 5° C./min, lowered to 30° C. at a rate of 20° C./min, and raised again at a rate of 5° C./min were evaluated, and a value ((ts150−ts30)/(150−30)) obtained by dividing the dimensional change by the temperature change was calculated and defined as the thermal expansion coefficient (as) of the layer A.

### Production Example

### A-1: Aromatic Polyester Amide (Liquid Crystal Polymer) Produced by the Production Method Described Below

### —Synthesis of Aromatic Polyester Amide A-1—

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature increases from 150° C. to 300° C. over five hours while by-produced acetic acid and unreacted acetic anhydride are distilled and is maintained at 300° C. for 30 minutes. Thereafter, a content is taken out from the reactor and is cooled to the room temperature. An obtained solid is ground by a grinder, and powdered aromatic polyester amide A1a is obtained. A flow start temperature of aromatic polyester amide A1a is 193° C. Aromatic polyester amide A1a is fully aromatic polyester amide.

Aromatic polyester amide A1a is subjected to solid-state polymerization by increasing the temperature from the room temperature to 160° C. over two hours and 20 minutes, next increasing the temperature from 160° C. to 180° C. over three hours and 20 minutes, and maintaining the temperature at 180° C. for five hours under a nitrogen atmosphere, and then, is cooled. Next, aromatic polyester amide A1a is pulverized by a pulverizer, and powdered aromatic polyester amide A1b is obtained. A flow start temperature of aromatic polyester amide A1b is 220° C.

The aromatic polyester amide A1b was subjected to solid-state polymerization by increasing the temperature from room temperature to 180° C. over 1 hour and 25 minutes in a nitrogen atmosphere, by increasing the temperature from 180° C. to 255° C. over 6 hours and 40 minutes, and by maintaining the temperature at 255° C. for 5 hours, and then the resultant was cooled, thereby obtaining a powdered aromatic polyester amide A-1.

A flow start temperature of aromatic polyester amide A-1 is 302° C. In addition, a melting point of the aromatic polyester amide A-1 measured by using a differential scanning calorimetry device was 311° C. Solubility of aromatic polyester amide A2 with respect to N-methylpyrrolidone at 140° C. was 1% by mass or more.

### B-1 and B-2: Fillers (Liquid Crystal Polymer Particles) Produced According to the Production Method Described Below

### —Production of Filler (Liquid Crystal Polymer Particles) B-1—

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst are put in a reactor comprising a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. A temperature increases from a room temperature to 150° C. over 15 minutes while stirring under a nitrogen gas flow, and refluxing is performed at 150° C. for two hours.

Next, the temperature increases from 150° C. to 310° C. over five hours while by-produced acetic acid and unreacted acetic anhydride are distilled, and a polymerized substance is taken out and is cooled to the room temperature. An obtained polymerized substance increases in temperature from the room temperature to 295° C. over 14 hours, and is subjected to solid-state polymerization at 295° C. for one hour. After the solid-state polymerization, the mixture was cooled to room temperature to obtain a liquid crystal polyester B1. The solubility of the second liquid crystal polyester B1 in N-methylpyrrolidone was less than 1% by mass.

The liquid crystal polyester B1 was pulverized using a jet mill (“KJ-200” manufactured by KURIMOTO, LTD.) to obtain particles (filler B-1) of the liquid crystal polyester B1. The obtained particles had a median diameter (D50) of 10 μm, a dielectric loss tangent of 0.0007, and a melting point of 319° C.

### —Production of Filler (Liquid Crystal Polymer Particles) B-2—

1034.99 g (5.5 mol) of hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as catalysts were placed. Gas in the reactor is substituted with nitrogen gas, and then, acetic anhydride (1.08 molar equivalent with respect to a hydroxyl group) is further added. A temperature increases from a room temperature to 150° C. over 15 minutes while stirring under a nitrogen gas flow, and refluxing is performed at 150° C. for two hours.

Next, the temperature increases from 150° C. to 310° C. over five hours while by-produced acetic acid and unreacted acetic anhydride are distilled, and a polymerized substance is taken out and is cooled to the room temperature. An obtained polymerized substance increases in temperature from the room temperature to 295° C. over 14 hours, and is subjected to solid-state polymerization at 295° C. for one hour. After the solid-state polymerization, the mixture was cooled to room temperature to obtain a liquid crystal polyester B1. The solubility of the second liquid crystal polyester B1 in N-methylpyrrolidone was less than 1% by mass.

The liquid crystal polyester B1 was pulverized using a jet mill (“KJ-200” manufactured by KURIMOTO, LTD.) to obtain particles (filler B-2) of the liquid crystal polyester B1. The obtained particles had a median diameter (D50) of 7 μm, a dielectric loss tangent of 0.0007, and a melting point of 319° C.

### B-3: Amorphous Silica Filler: Median Diameter (D50) of 2 μm, Dielectric Loss Tangent of 0.001, Melting Point of 1710° C.

C-1: Thermoplastic particles produced according to the production method described below
—Production of thermoplastic particles C-1—

TAFTEC M1913 manufactured by Asahi Kasei Corporation was pulverized to obtain thermoplastic particles C-1 (average particle diameter: 5 μm (D50), thermoplastic particles, elastomer particles containing a constitutional unit having an aromatic hydrocarbon group).

### Examples 1 and 2 and Comparative Examples 1 and 2

### —Preparation of Coating Liquid for Undercoat Layer—

8 parts of aromatic polyester amide A-1 was added to 92 parts of N-methylpyrrolidone, and the mixture was stirred at 140° C. for 4 hours under a nitrogen atmosphere to obtain an aromatic polyester amide solution P1 (concentration of solid contents: 8% by mass).

An aminophenol type epoxy resin (“jER630” manufactured by Mitsubishi Chemical Corporation, 0.04 parts by mass) was mixed with the aromatic polyester amide solution P1 (10.0 parts by mass) to prepare an undercoat layer coating liquid.

### —Preparation of Coating Liquid for Layer A—

The aromatic polyester amide and the filler shown in Table 1 were mixed at the ratios in parts by mass shown in Table 1, N-methylpyrrolidone was added thereto to adjust the concentration of solid contents to 20% by mass, and a coating liquid for a layer A was obtained.

### —Preparation of Coating Liquid for Layer B—

The aromatic polyester amide and the thermoplastic particles shown in Table 1 were mixed at the ratios in parts by mass shown in Table 1, N-methylpyrrolidone was added thereto to adjust the concentration of solid contents to 20% by mass, and a coating liquid for a layer B was obtained.

### —Preparation of Single-Sided Copper-Clad Laminated Plate—

The obtained undercoat layer coating liquid and the coating liquid for the layer A were fed to a slot die coater equipped with a slide coater, and applied onto a treatment surface of a copper foil (product name “CF-T9DA-SV-18”, average thickness: 18 μm, manufactured by Fukuda Metal Foil & Powder Co., Ltd.) in a two-layer configuration (undercoat layer/layer A) by adjusting a flow rate so that the film thicknesses shown in Table 1 were obtained. The solvent was removed from the coating film by drying at 50° C. for 3 hours. In Example 2, the undercoat layer coating liquid, the coating liquid for the layer A, and the coating liquid for the layer B were fed to a slot die coater equipped with a slide coater, and applied onto the treatment surface of the above-described copper foil in a three-layer configuration (undercoat layer/layer A/layer B) by adjusting the flow rate so that the film thicknesses shown in Table 1 were obtained. The solvent was removed from the coating film by drying at 50° C. for 3 hours.

The temperature was further raised from room temperature to 300° C. at 1° C./min in a nitrogen atmosphere, and the heat treatment was performed for 3 hours at that temperature to obtain a polymer film having a copper layer (a single-sided copper-clad laminated plate).

### <<Evaluation>>

The produced films were evaluated by the following methods, and the results are shown in Table 1.

### [Dielectric Loss Tangent]

The dielectric loss tangent was measured by a resonance perturbation method at a frequency of 10 GHz. A 10 GHz cavity resonator (CP531 manufactured by KANTO Electronic Application and Development Inc.) is connected to a network analyzer (“E8363B” manufactured by Agilent Technology Co., Ltd.), the test piece is inserted into the cavity resonator, and the dielectric loss tangent of the film is measured from change in resonance frequency before and after insertion for 96 hours under an environment of a temperature of 25° C. and humidity of 60% RH.

### [Breaking Elongation]

The breaking strength of the layer A was measured by the following method.

The film was cut out to have a length of 200 mm (in the measurement direction) and a width of 10 mm. A distance between chucks was set to 100 mm, and using a universal tensile tester “STM T50BP” manufactured by Toyo Baldwin Co., Ltd., the measurement was performed at a tensile rate of 10%/min in an atmosphere of 25° C. and 60% RH until the sample was broken, and the breaking elongation was calculated.

### [Curl Suppressing Property]

The produced film was cut into a size of 10 cm×10 cm to obtain a test piece.

The test piece was disposed on the platform so that the copper foil side of the test piece was in contact with the platform. A rod-shaped weight was placed on the diagonal line of the surface of the test piece.

Next, the shape of the film was observed from a direction parallel to the main surface of the film. In a case where the film had an arc shape, a peel height of the film was measured. The peel height is a height from a platform of a vertex on a side on which the weight of the film is not placed. The evaluation standards are as follows.

### (Evaluation Standard)

A: The film had an arc shape, and the peel height was 24 mm or less.
B: The film had an arc shape, and the peel height was more than 24 mm.
C: The film was in an annular shape.

TABLE 1

| | Layer A | | | | | | | | | | | |
|---|---|---|---|---|---|---|---|---|---|---|---|---|
| | Aromatic | | | | | | | | | | | |
| | polyester amide | | Filler | | | | Elastic | Elastic | | | | |
| | | Content | | Content | Bulk | Porosity | modulus | modulus | CTE | Breaking | Dielectric | |
| | | [% by | | [% by | density | [% by | (25° C.) | (160° C.) | [ppm/ | elongation | loss | Thickness |
| | Type | mass] | Type | mass] | [g/cm³] | volume] | [GPa] | [GPa] | ° C.] | [%] | tangent | [μm] |
| Example 1 | A-1 | 25 | B-1 | 75 | 1.0 | 24 | 1.5 | 0.4 | 51 | 10 | 0.002 | 30 |
| Example 2 | A-1 | 25 | B-1 | 75 | 1.0 | 24 | 1.5 | 0.4 | 51 | 10 | 0.002 | 30 |
| Comparative | A-1 | 25 | B-2 | 75 | 1.2 | 11 | 2.3 | 0.1 | 48 | 20 | 0.002 | 30 |
| Example 1 | | | | | | | | | | | | |
| Comparative | A-1 | 25 | B-3 | 75 | 1.8 | 0 | 6.1 | 1.2 | 29 | 2 | 0.003 | 30 |
| Example 2 | | | | | | | | | | | | |

| | Layer B | | | | | | | | |
|---|---|---|---|---|---|---|---|---|---|
| | Aromatic | | Thermoplastic | | | Ratio of elastic | | | |
| | polyester amide | | particles | | Elastic | modulus (elastic | | | |
| | | Content | | Content | modulus | modulus of layer A/ | Dielectric | | Curl |
| | | [% by | | [% by | (160° C.) | elastic modulus of | loss | Thickness | suppressing |
| | Type | mass] | Type | mass] | [GPa] | layer B) (160° C.) | tangent | [μm] | property |
| Example 1 | — | — | — | — | — | — | — | — | A |
| Example 2 | A-1 | 20 | C-1 | 80 | 0.05 | 8 | 0.002 | 15 | A |
| Comparative | — | — | — | — | — | — | — | — | B |
| Example 1 | | | | | | | | | |
| Comparative | — | — | — | — | — | — | — | — | A |
| Example 2 | | | | | | | | | |

From the results shown in Table 1, the films of Examples 1 and 2 which are the films according to the embodiment of the present disclosure have excellent curl suppressing property and high breaking elongation as compared with the films of Comparative Examples 1 and 2.

The entire disclosure of Japanese Patent Application No. 2022-138491, filed Aug. 31, 2022, is incorporated into the present specification by reference.

All documents, patent applications, and technical standards described in the present specification are incorporated into the present specification by reference, as if each of the documents, the patent applications, and the technical standards is specifically and individually described.

What is claimed is:

1. A film comprising:
a layer A having a dielectric loss tangent of 0.01 or less, a thermal expansion coefficient of 30 ppm/K to 70 ppm/K, and a porosity of 20% by volume to 60% by volume.

2. The film according to claim 1,
wherein an elastic modulus of the layer A at 25° C. is 1.0 GPa or more.

3. The film according to claim 1,
wherein a bulk density of the layer A is 1.3 g/cm³ or less.

4. The film according to claim 1,
wherein a layer B is provided on at least one surface of the layer A,
an elastic modulus of the layer A at 160° C. is 0.1 GPa to 2.5 GPa, and
a ratio of an elastic modulus of the layer A at 160° C. to an elastic modulus of the layer B at 160° C. is 1.2 or more.

5. The film according to claim 4,
wherein the elastic modulus of the layer B at 160° C. is 0.1 GPa or less.

6. The film according to claim 1,
wherein the layer A contains a liquid crystal polymer.

7. The film according to claim 1,
wherein the layer A contains an aromatic polyester amide.

8. The film according to claim 4,
wherein a dielectric loss tangent of the layer B is 0.01 or less.

9. The film according to claim 4,
wherein the layer B contains a liquid crystal polymer.

10. The film according to claim 4,
wherein the layer B contains an aromatic polyester amide.

11. The film according to claim 4,
wherein the layer B contains at least one of a resin having a constitutional unit having an aromatic hydrocarbon group or an elastomer having a constitutional unit having an aromatic hydrocarbon group.

12. A laminate comprising, in the following order:
a layer A; and
a metal layer or a metal wire,
wherein the layer A has a dielectric loss tangent of the layer A is 0.01 or less, a thermal expansion coefficient of the layer A is 30 ppm/K to 70 ppm/K, and a porosity of the layer A is 20% by volume to 60% by volume.
